(19) United States
(12) Patent Application Publication
(10) Pub. No.: US 2025/0141356 A1
(43) Pub. Date: May 1, 2025

(54) DC-DC CONVERTER

(71) Applicant: ADRC. CO. KR, Seoul (KR)

(72) Inventors: Jin JANG, Seoul (KR); PRIYADARSHI SUNAINA, Seoul (KR); Jun Hyuk CHEON, Seoul (KR)

(21) Appl. No.: 18/925,319

(22) Filed: Oct. 24, 2024

(30) Foreign Application Priority Data
Oct. 30, 2023 (KR) 10-2023-0146934
Sep. 23, 2024 (KR) 10-2024-0128287

(51) Int. Cl. H02M 3/158; H01L 29/786

(52) U.S. Cl. CPC H02M 3/158; H10D 30/6731; H10D 30/6734; H10D 30/6745; H10D 30/6755

(57) ABSTRACT

A DC-DC converter may include a first transistor that includes one terminal to which an input voltage is provided, a second transistor that includes one terminal connected to another terminal of the first transistor, a third transistor that includes one terminal to which the input voltage is provided, a fourth transistor that includes one terminal connected to another terminal of the third transistor, a fifth transistor that has a diode connection with another terminal of the second transistor, a sixth transistor that has a diode connection with another terminal of the fourth transistor, a first capacitor that includes one terminal connected to the gate of the fifth transistor, and another terminal to which a first clock signal is provided, and a second capacitor that includes one terminal connected to the gate of the sixth transistor, and another terminal to which a second clock signal is provided.

### CROSS-REFERENCE TO RELATED APPLICATION

This application claims priority to and the benefit of Korean Patent Application No. 10-2023-0146934 filed in the Korean Intellectual Property Office on Oct. 30, 2023, and Korean Patent Application No. 10-2024-0128287 filed in the Korean Intellectual Property Office on Sep. 23, 2024, the entire contents of which are incorporated herein by reference.

### BACKGROUND

### (a) Technical Field

The present disclosure relates to a DC-DC converter.

### (b) Description of the Related Art

The demand for small integrated circuits for system-on-chip is increasing. A DC-DC converter may convert a supplied DC voltage into an appropriate DC voltage level. A driver integrated in a display device should supply a high voltage of 8 V to 20 V to turn on a switching TFT and a drive TFT in an active matrix display pixel circuit. A DC-DC converter made as a PMOS or CMOS LTPS TFT has a disadvantage in that the LTPS TFT has a high off-state current (−10⁻¹⁰ A). A complicated a-IGZO-based DC-DC converter requires a number of capacitors, a CMOS bootstrap inverter, and a NAND gate. A threshold voltage (VTH) drop limits low-voltage operation in an oxide DC-DC converter application. An oxide DC-DC converter may lack a stable p-type oxide TFT, whereby the drive capability may be limited.

### SUMMARY

The present disclosure attempts to provide a DC-DC converter including an oxide TFT.

A DC-DC converter may include a first transistor that includes one terminal to which an input voltage is provided, a second transistor that includes one terminal connected to another terminal of the first transistor, a third transistor that includes one terminal to which the input voltage is provided, a fourth transistor that includes one terminal connected to another terminal of the third transistor, a fifth transistor is a diode connection with another terminal of the second transistor, a sixth transistor that is a diode connection with another terminal of the fourth transistor, a first capacitor that includes one terminal connected to the gate of the fifth transistor, and another terminal to which a first clock signal is provided, and a second capacitor that includes one terminal connected to the gate of the sixth transistor, and another terminal to which a second clock signal is provided.

The first transistor and the second transistor may be implemented as low-temperature polycrystalline silicon and oxide thin-film transistors (LTPO TFTs).

The third transistor and the fourth transistor may be implemented as low-temperature polycrystalline silicon and oxide thin-film transistors (LTPO TFTs).

The second transistor and the fifth transistor may be implemented as low-temperature polycrystalline silicon and oxide thin-film transistors (LTPO TFTs).

The fourth transistor and the sixth transistor may be implemented as low-temperature polycrystalline silicon and oxide thin-film transistors (LTPO TFTs).

The DC-DC converter may further include a third capacitor that includes one terminal connected to the gate of the third transistor, and another terminal to which the first clock signal is provided, and a fourth capacitor that includes one terminal connected to the gate of the second transistor, and another terminal to which the second clock signal is provided.

When the third transistor is turned on and the fourth transistor is turned off by the first clock signal, the gate of the sixth transistor may be charged with a voltage through the second capacitor by the first clock signal, and a load capacitor connected to an output node may be charged by the voltage of the gate of the sixth transistor, whereby an output voltage may be provided.

When the first transistor is turned off and the second transistor is turned on by the second clock signal, the voltage of the gate of the fifth transistor may be discharged through the first capacitor by the second clock signal, whereby the fifth transistor may be turned off.

When the first transistor is turned on and the second transistor is turned off by the second clock signal, the gate of the fifth transistor may be charged with a voltage through the first capacitor by the second clock signal, and a load capacitor connected to an output node may be charged by the voltage of the gate of the fifth transistor, whereby an output voltage may be provided.

When the third transistor is turned off and the fourth transistor is turned on by the first clock signal, the voltage of the gate of the sixth transistor may be discharged through the second capacitor by the first clock signal, whereby the sixth transistor may be turned off.

The present disclosure can provide a DC-DC converter using an LTPO CMOS circuit including a p-type LTPS and an n-type oxide TFT. By applying a p-type LTPS TFT, it is possible to alleviate the VTH drop limit and improve mobility, and by using an oxide TFT, it is possible to reduce an off-current. Further, it is possible to provide a stable DC-DC converter by increasing a drain current using a double-gate (DG) oxide TFT in place of a single-gate oxide TFT.

### BRIEF DESCRIPTION OF THE DRAWINGS

FIG. 1 is a cross-sectional view illustrating the structure of a complementary transistor according to an exemplary embodiment.

FIG. 2 is a circuit diagram illustrating a DC-DC converter according to an exemplary embodiment.

FIG. 3 is a waveform diagram illustrating the waveforms of two clock signals, and voltages, an input voltage, and an output voltage in a DC-DC converter according to an exemplary embodiment.

### DETAILED DESCRIPTION OF THE EMBODIMENTS

Hereinafter, exemplary embodiments disclosed in this specification will be described in detail with reference to the accompanying drawings; however, the same or similar constituent elements are denoted by the same or similar reference symbols, and a repeated description thereof will not be made.

Further, when describing exemplary embodiments disclosed in this specification, detailed descriptions of publicly known technologies will be omitted if it is determined that specific description thereof may obscure the gist of the exemplary embodiments disclosed in this specification. Furthermore, the accompanying drawings are provided for helping to easily understand exemplary embodiments disclosed in the present specification, and the technical spirit disclosed in the present specification is not limited by the accompanying drawings, and it will be appreciated that the present invention includes all of the modifications, equivalent matters, and substitutes included in the spirit and the technical scope of the present invention.

Terms including an ordinal number, such as first and second, are used for describing various constituent elements, but the constituent elements are not limited by the terms. The terms are used only to discriminate one constituent element from another constituent element.

When a constituent element is referred to as being “connected” or “coupled” to another constituent element, it will be appreciated that it may be directly connected or coupled to the other constituent element or intervening other constituent elements may be present. In contrast, when a constituent element is referred to as being “directly connected” or “directly coupled” to another constituent element, it will be appreciated that there are no intervening other constituent elements present.

In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Hereinafter, a complementary transistor according to an exemplary embodiment will be described.

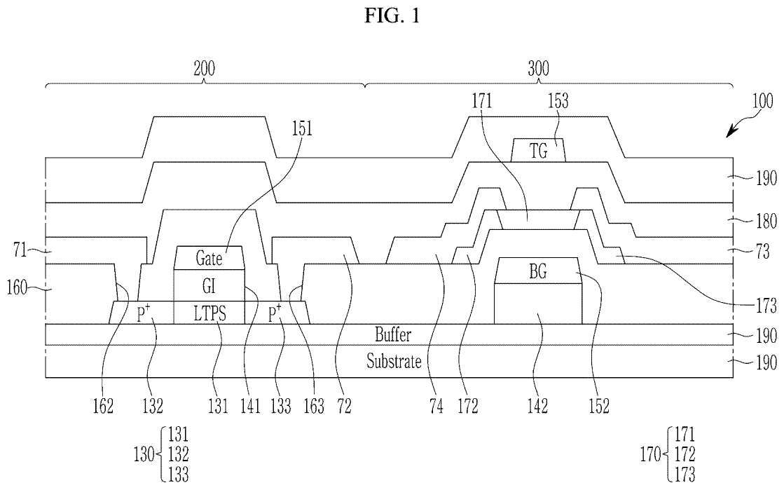

FIG. 1 is a cross-sectional view illustrating the structure of a complementary transistor according to an exemplary embodiment.

A transistor 100 according to an exemplary embodiment includes a first transistor 200 and a second transistor 300. The transistor 100 may be implemented as a low-temperature polycrystalline silicon and oxide thin-film transistor (LTPO TFT). The first transistor 200 may be a low-temperature polycrystalline silicon (LTPS) TFT. The second transistor 300 may be implemented as an oxide TFT, for example, as an amorphous-indium-gallium-zinc-oxide (a-IGZO) TFT which is an example of the oxide TFT.

In a process of crystallizing a-Si of the first transistor 200, blue laser annealing (BLA) may be used. Then, high mobility due to a larger grain size as compared to excimer laser annealing (ELA) may be provided. The second transistor 300 may be a double-gate (DG) n-type TFT. The second transistor 300 may be formed by back channel etch (BCE). The top gate (TG) and bottom gate (BG) of the second transistor 300 may be electrically connected such that the on-state current of the second transistor 300 is high and the threshold voltage is constant at 0 V. In respect to a specific manufacturing process of the first and second transistors 200 and 300, the following two well-known papers may be referred to. Therefore, a detailed description of the manufacturing process will not be made. The case where the second transistor 300 is a double-gate structure is an example for describing an exemplary embodiment, and the second transistor 300 of the present invention may be implemented as a single-gate oxide TFT.
1) A. Rahaman, H. Jeong and J. Jang, “A High-Gain CMOS Operational Amplifier Using Low-Temperature Poly-Si Oxide TFTs,” IEEE Transactions on Electron Devices, Vol. 67, No. 2, pp. 524-528, February 2020.
2) Y. Chen, S. Lee, H. Kim, J. Lee, D. Geng, and J. Jang, “In-pixel temperature sensor for high-luminance active matrix micro-light-emitting diode display using low-temperature polycrystalline silicon and oxide thin-film-transistors,” J. Soc. Inf. Display, Vol. 28, No. 6, pp. 528-534, May 2020.

Referring to FIG. 1, a buffer layer 120 is positioned on a substrate 110. The buffer layer 120 may have a single layer or multi-layer structure. In FIG. 1, the buffer layer 120 is shown as a single layer; however, in some exemplary embodiments, the buffer layer may consist of multiple layers. The buffer layer 120 may contain an organic insulating material or an inorganic insulating material. As an example, the buffer layer 120 may contain at least one of silicon nitride (SiNₓ), silicon oxide (SiOₓ), and silicon oxynitride (SiOₓN_{y}).

On the buffer layer 120, a first semiconductor layer 130 which includes a first region 131, a second region 132, and a third region 133 is positioned.

The semiconductor layer 130 may contain poly-silicon, for example, low temperature poly-silicon.

The first region 131 of the semiconductor layer 130 is a channel region, and the second region 132 and the third region 133 of the first semiconductor layer (131, 132, and 133) may be a source region and a drain region.

The sheet resistance of the first region 131 which is the channel region of the first semiconductor layer (131, 132, and 133) is larger than the sheet resistance of the second region 132 and the third region 133 which are the source region and drain region of the first semiconductor layer (131, 132, and 133), and the carrier concentration of the first region 131 which is the channel region of the first semiconductor layer (131, 132, and 133) is lower than the carrier concentrations of the second region 132 and the third region 133 which are the source region and drain region of the first semiconductor layer (131, 132, and 133).

The first region 131 which is the channel region of the first semiconductor layer (131, 132, and 133) may not contain impurities. The concentrations of impurities in the second region 132 and third region 133 of the first semiconductor layer (131, 132, and 133) may be higher than the concentration of impurities in the first region 131 of the first semiconductor layer (131, 132, and 133).

The second region 132 and the third region 133 of the first semiconductor layer (131, 132, and 133) may contain impurities, for example, N-type impurities or P-type impurities. For example, the N-type impurities may be phosphorus (P), arsenic (As), or antimony (Sb), and the P-type impurities may be boron (B), aluminum (Al), or indium (In).

On the first region 131 of the first semiconductor layer (131, 132, and 133), a gate insulating film (GI) 141 is positioned. The gate insulating film 141 may contain an organic insulating material or an inorganic insulating material, and as an example, the gate insulating film 141 may contain at least one of silicon nitride, silicon oxide, silicon oxynitride, and tetra ethyl ortho silicate (TEOS).

On the gate insulating film 141, a first gate electrode 151 is positioned. The first gate electrode 151 is disposed so as to overlap the first region 131 of the first semiconductor layer (131, 132, and 133), and the gate insulating film 141 is positioned between the first region 131 of the first semiconductor layer (131, 132, and 133) and the gate electrode 151.

The first gate electrode 151 may be a multi-layer film including a metal film containing at least one of copper (Cu), a copper alloy, aluminum (AI), an aluminum alloy, molybdenum (Mo), and a molybdenum alloy.

An insulating pattern 142 may be positioned on the buffer layer 120. On the insulating pattern 142, a bottom gate (BG) electrode 152 may be positioned. The insulating pattern 142 and the gate insulating film 141 may be formed in the same process step, the bottom gate electrode 152 and the first gate electrode 151 may be formed in the same process step.

On the first semiconductor layer (131, 132, and 133), the first gate electrode 151, and the bottom gate electrode 152, a passivation layer 160 is positioned. The passivation layer 160 may contain at least one of silicon nitride, silicon oxide, silicon oxynitride, and tetra ethyl ortho silicate (TEOS), and may be formed of an organic material such as a polyacrylates resin or a polyimides resin, or a laminated film of an organic material and an inorganic material.

The passivation layer 160 has a first contact hole 162 which overlaps the second region 132 of the first semiconductor layer (131, 132, and 133), and a second contact hole 163 which overlaps the third region 133 of the first semiconductor layer (131, 132, and 133).

On the passivation layer 160, a second semiconductor layer (171, 172, and 173) which overlaps the bottom gate electrode 152 and includes a first region 171, a second region 172, and a third region 173 is positioned. The second semiconductor layer (171, 172, and 173) may contain an oxide semiconductor.

The oxide semiconductor may contain at least one of oxides of single-component metals such as oxides of indium (In), oxides of tin (Sn), or oxides of zinc (Zn), oxides of two-component metals such as In—Zn-based oxides, Sn—Zn-based oxides, Al—Zn-based oxides, Zn—Mg-based oxides, Sn—Mg-based oxides, In—Mg-based oxides, or In—Ga-based oxides, oxides of three-component metals such as In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy—Zn-based oxides, In—Ho—Zn-based oxides, In—Er—Zn-based oxides, In—Tm—Zn-based oxides, In—Yb—Zn-based oxides, or In—Lu—Zn-based oxides, and oxides of four-component metals such as In—Sn—Ga—Zn-based oxides, In—Hf—Ga—Zn-based oxides, In—Al—Ga—Zn-based oxides, In—Sn—Al—Zn-based oxides, In—Sn—Hf—Zn-based oxides, or In—Hf—Al—Zn-based oxides. For example, the second semiconductor layer (171, 172, and 173) may contain an indium-gallium-zinc oxide (IGZO) of the In—Ga—Zn-based oxides.

The second semiconductor layer (171, 172, and 173) may contain at least one of indium-gallium-zinc oxide (IGZO), indium-zinc-tin oxide (IZTO), indium-gallium-zinc-tin oxide (IGZTO), and indium-gallium oxide (IGO).

The first region 171 of the second semiconductor layer (171, 172, and 173) is a channel region, and the second region 172 and third region 173 of the second semiconductor layer (171, 172, and 173) may be a source region and a drain region.

On the passivation layer 160, a first source electrode 71 and a first drain electrode 72 are positioned, and on the passivation layer 160 and the second semiconductor layer (171, 172, and 173), a second source electrode 73 and a second drain electrode 74 are positioned.

The first source electrode 71 and the first drain electrode 72 are coupled to the second region 132 which is the source region of the first semiconductor layer (131, 132, and 133) and the third region 133 which is the drain region of the first semiconductor layer (131, 132, and 133) through the first contact hole 162 and the second contact hole 163 in the passivation layer 160.

The second source electrode 73 and the second drain electrode 74 may be positioned on the second region 172 which is the source region of the second semiconductor layer (171, 172, and 173) and the third region 173 which is the drain region of the second semiconductor layer (171, 172, and 173).

The first source electrode 71, the first drain electrode 72, the second source electrode 73, and the second drain electrode 74 may contain an aluminum-based metal, a silver-based metal, and a copper-based metal having low specific resistance, and may be, for example, a triple-layer structure of a lower film containing a refractory metal such as titanium, molybdenum, chromium, and tantalum, or an alloy thereof, an intermediate film containing an aluminum-based metal, a silver-based metal, or a copper-based metal having low specific resistance, and an upper film containing a refractory metal such as titanium, molybdenum, chromium, and tantalum, or an alloy thereof.

On the first source electrode 71, the first drain electrode 72, the second source electrode 73, and the second drain electrode 74, a second gate insulating film 180 may be positioned, and on the second gate insulating film 180, a top gate (TG) electrode 153 may be positioned.

The top gate electrode 153 and the bottom gate electrode 152 may overlap the first region 171 which is the channel region of the second semiconductor layer (171, 172, and 173).

On the top gate electrode 153, a second passivation layer 190 may be positioned.

The first semiconductor layer (131, 132, and 133) may form the first transistor 200 together with the first gate electrode 151, the first source electrode 71, and the first drain electrode 72. The channel region of the first transistor 200 may be formed in the first region 131 between the second region 132 and third region 133 of the first semiconductor layer (131, 132, and 133).

Similarly, the second semiconductor layer (171, 172, and 173) may form the second transistor 300 together with the bottom gate electrode 152, the top gate electrode 153, the second source electrode 73, and the second drain electrode 74. The channel region of the second transistor 300 is formed in the first region 171 between the second region 172 and third region 173 of the second semiconductor layer (171, 172, and 173).

Although not shown in FIG. 1, in at least one of the second gate insulating film 180 and the second passivation layer 190, a contact hole for coupling the first source electrode 71 and the second source electrode 73 to a line (not shown in the drawings) for supplying a predetermined voltage may be positioned. Also, in at least one of the second gate insulating film 180 and the second passivation layer 190, a contact hole for coupling the first drain electrode 72 and the second drain electrode 74 to each other may be positioned.

In the description made with reference to FIG. 1, the source electrode and the drain electrode are terms for distinguishing two electrodes constituting the transistor; however, unlike in the above description, the source electrode may be a drain electrode and the drain electrode may be a source electrode.

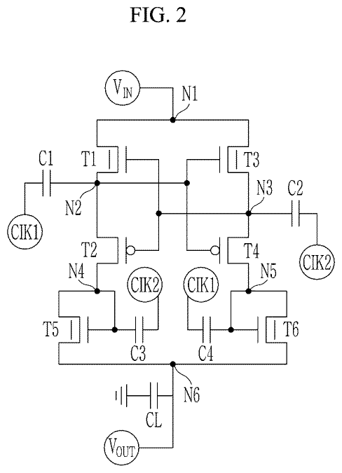

FIG. 2 is a circuit diagram illustrating a DC-DC converter according to an exemplary embodiment.

A DC-DC converter 10 may include six transistors T1 to T6 and five capacitors C1, C2, C3, C4, and CL. At least a pair of two transistors T1 and T2, two transistors T3 and T4, two transistors T2 and T5, and two transistors T4 and T6 may be implemented as the complementary transistor shown in FIG. 1. Four transistors T1, T3, T5, and T6 may be implemented as a double-gate a-IGZO TFT, and two transistors T2 and T4 may be implemented as a single-gate LTPS TFT.

The DC-DC converter 10 may generate an output voltage VOUT using two clock signals CLK1 and CLK2 having a phase difference of 180° while an input voltage VIN is supplied.

The input voltage VIN is supplied to a node N1, and the drain of the transistor T1 and the drain of the transistor T3 are connected to the node N1. The source of the transistor T1 and the gate of the transistor T3 are connected to a node N2, and the source of the transistor T3 and the gate of the transistor T1 are connected to a node N3. One terminal of the capacitor C1 is connected to the node N2, and the clock signal CLK1 is applied to the other terminal of the capacitor C1. One terminal of the capacitor C2 is connected to the node N3, and the clock signal CLK2 is applied to the other terminal of the capacitor C2. The source of the transistor T2 is connected to the node N2, and the gate of the transistor T2 is connected to the node N3, and the drain of the transistor T2 is connected to a node N4. The drain and gate of the transistor T5 are connected to the node N4 such that the transistor T5 is in a diode connection state. The drain and gate of the transistor T6 are connected to a node N5 such that the transistor T6 is in a diode connection state. One terminal of the capacitor C3 is connected to the node N4, and the clock signal CLK2 is applied to the other terminal of the capacitor C3. One terminal of the capacitor C4 is connected to the node N5, and the clock signal CLK1 is applied to the other terminal of the capacitor C4. The source of each of the transistor T5 and the transistor T6 is connected to a node N6, and a voltage which is provided to the node N6 is the output voltage VOUT. In other words, the node N6 is an output node, and the load capacitor CL is formed between the node N6 and a ground. The load capacitor CL may include at least one capacitor which is electrically connected to the node N6. For example, the load capacitor CL may include a parasitic capacitor connected to the node N6, a capacitor which is provided to the node N6 in a load to which the output voltage VOUT is supplied.

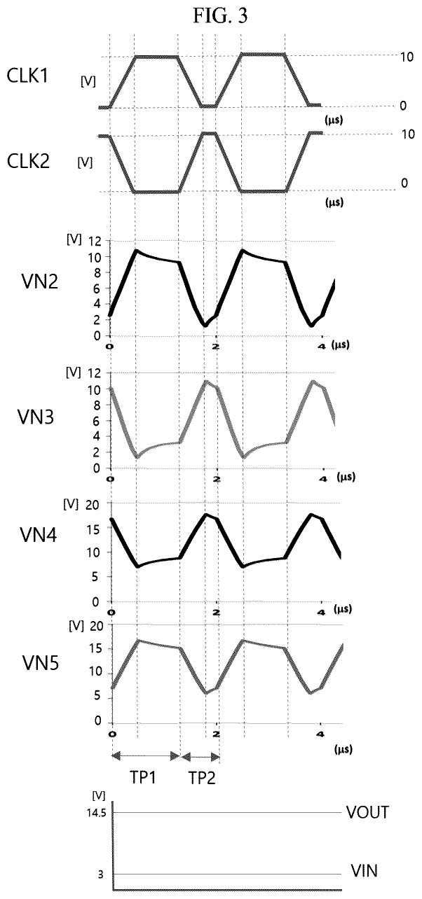

FIG. 3 is a waveform diagram illustrating the waveforms of two clock signals, and voltages, an input voltage, and an output voltage in a DC-DC converter according to an exemplary embodiment.

As shown in FIG. 3, the phase difference between the two clock signals CLK1 and CLK2 is 180°, and their phases are inverted from each other. When an input voltage VIN equal to or higher than a predetermined level is supplied to the DC-DC converter 10, the DC-DC converter 10 may operate. The clock signal CLK1 and the clock signal CLK2 may swing from 0 V to 10 V, and have a frequency of 500 KHz and a cycle of 2 μs. Under this condition, the DC-DC converter 10 may generate 14.5 V as the output voltage VOUT in response to the input voltage VIN.

In a period TP1, the clock signal CLK1 rises to the high level and is maintained, and the clock signal CLK2 falls to the low level and is maintained. The clock signal CLK1 may be supplied to the node N2 through the capacitor C1 such that the voltage VN2 at the node N2 rises and then slightly decreases according to the waveform of the clock signal CLK1 to reach 10 V. The clock signal CLK2 at the low level may be supplied to the node N3 through the capacitor C2 such that the voltage VN3 at the node N3 decreases and then slightly increases according to the waveform of the clock signal CLK2 to reach 3 V in response to an input voltage VIN2. In the period TP1, the voltage VN2 may be at a level to turn on the transistor T3 and turn off the transistor T4, and the voltage VN3 may be at a level to turn off the transistor T1 and turn on the transistor T2. By turning on the transistor T3, the input voltage VIN may be provided to the node N3.

In the period TP1, since the clock signal CLK1 is supplied to the node N5 through the capacitor C4, the node N5 may be charged. Since the transistor T6 is in the diode connection state, as the node N5 is charged, the output voltage VOUT to be stored in the load capacitor CL may increase.

The voltage at the node N5 may be maintained at a voltage higher than the high level of the clock signal CLK1 by the voltage stored in the capacitor C4, and a voltage higher than the high level of the clock signal CLK1 may be generated as the output voltage VOUT according to the voltage at the node N5. For example, when the high level of the clock signal CLK1 is 10 V, the output voltage VOUT may be generated with 14.5 V. Since the clock signal CLK2 is supplied to the node N4 through the capacitor C3, the node N4 may be discharged. Although the transistor T5 is in the diode connection state, the voltage VN4 at the node N4 becomes a voltage lower than the output voltage of the node N6, so the transistor T5 is not turned on. Specifically, in the period TP1, since the output voltage VOUT is 14.5 V and the voltage VN4 decreases according to the clock signal CLK2 to become a voltage lower than 14.5 V, the transistor T5 is controlled so as to be off.

In a period TP2, the clock signal CLK2 rises to the high level and is maintained, and the clock signal CLK1 falls to the low level and is maintained. The clock signal CLK1 may be supplied to the node N2 through the capacitor C1 such that the voltage VN2 at the node N2 falls and then slightly increases according to the waveform of the clock signal CLK1 to reach 2 V. The clock signal CLK2 at the low level may be supplied to the node N3 through the capacitor C2 such that the voltage VN3 at the node N3 increases and then slightly decreases according to the waveform of the clock signal CLK2 to reach 10 V. In the period TP2, the voltage VN2 may be at a level to turn off the transistor T3 and turn on the transistor T4, and the voltage VN3 may be at a level to turn on the transistor T1 and turn off the transistor T2. By turning on the transistor T1, the input voltage VIN may be provided to the node N2.

In the period TP2, since the clock signal CLK2 is supplied to the node N4 through the capacitor C3, the node N4 may be charged. Since the transistor T5 is in the diode connection state, as the node N4 is charged, the output voltage VOUT to be stored in the load capacitor CL may increase. The voltage at the node N4 may be maintained at a voltage higher than the high level of the clock signal CLK2 by the voltage stored in the capacitor C3, and a voltage higher than the high level of the clock signal CLK2 may be generated as the output voltage VOUT according to the voltage at the node N4. For example, when the high level of the clock signal CLK2 is 10 V, the output voltage VOUT may be generated with 14.5 V. Since the clock signal CLK1 is supplied to the node N5 through the capacitor C4, the node N5 may be discharged. Although the transistor T6 is in the diode connection state, the voltage VN5 at the node N5 becomes a voltage lower than the output voltage of the node N6, so the transistor T6 is not turned on. Specifically, in the period TP2, since the output voltage VOUT is 14.5 V and the voltage VN5 decreases according to the clock signal CLK1 to become a voltage lower than 14.5 V, the transistor T6 is controlled so as to be off.

As described above, the DC-DC converter according to the exemplary embodiment may supply voltages having appropriate levels to the gates of the transistors T1 to T4 constituting the DC-DC converter in response to an input voltage VIN of 3 V, using the two clock signals CLK1 and CLK2. Then, the DC-DC converter may generate the output voltage VOUT of 14.5 V equal to or higher than a level obtained by adding the high level of the clock signal CLK1 or CL2 to the level of the input voltage VIN.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

What is claimed is:

1. A DC-DC converter comprising:
a first transistor that includes one terminal to which an input voltage is provided;
a second transistor that includes one terminal connected to another terminal of the first transistor;
a third transistor that includes one terminal to which the input voltage is provided;
a fourth transistor that includes one terminal connected to another terminal of the third transistor;
a fifth transistor configured to be a diode connection with another terminal of the second transistor;
a sixth transistor configured to be a diode connection with another terminal of the fourth transistor;
a first capacitor that includes one terminal connected to the gate of the fifth transistor, and another terminal to which a first clock signal is provided; and
a second capacitor that includes one terminal connected to the gate of the sixth transistor, and another terminal to which a second clock signal is provided.

2. The DC-DC converter of claim 1, wherein:
the first transistor and the second transistor are implemented as low-temperature polycrystalline silicon and oxide thin-film transistors (LTPO TFTs).

3. The DC-DC converter of claim 1, wherein:
the third transistor and the fourth transistor are implemented as low-temperature polycrystalline silicon and oxide thin-film transistors (LTPO TFTs).

4. The DC-DC converter of claim 1, wherein:
the second transistor and the fifth transistor are implemented as low-temperature polycrystalline silicon and oxide thin-film transistors (LTPO TFTs).

5. The DC-DC converter of claim 1, wherein:
the fourth transistor and the sixth transistor are implemented as low-temperature polycrystalline silicon and oxide thin-film transistors (LTPO TFTs).

6. The DC-DC converter of claim 1, further comprising:
a third capacitor that includes one terminal connected to the gate of the third transistor, and another terminal to which the first clock signal is provided; and
a fourth capacitor that includes one terminal connected to the gate of the second transistor, and another terminal to which the second clock signal is provided.

7. The DC-DC converter of claim 1, wherein:
when the third transistor is turned on and the fourth transistor is turned off by the first clock signal, the gate of the sixth transistor is charged with a voltage through the second capacitor by the first clock signal, and a load capacitor connected to an output node is charged by the voltage of the gate of the sixth transistor, whereby an output voltage is provided.

8. The DC-DC converter of claim 7, wherein:
when the first transistor is turned off and the second transistor is turned on by the second clock signal, the voltage of the gate of the fifth transistor is discharged through the first capacitor by the second clock signal, whereby the fifth transistor is turned off.

9. The DC-DC converter of claim 1, wherein:
when the first transistor is turned on and the second transistor is turned off by the second clock signal, the gate of the fifth transistor is charged with a voltage through the first capacitor by the second clock signal, a load capacitor connected to an output node is charged by and the voltage of the gate of the fifth transistor, whereby an output voltage is provided.

10. The DC-DC converter of claim 9, wherein:
when the third transistor is turned off and the fourth transistor is turned on by the first clock signal, the voltage of the gate of the sixth transistor is discharged through the second capacitor by the first clock signal, whereby the sixth transistor is turned off.
